(19) United States
(12) Patent Application Publication
(10) Pub. No.: US 2010/0239784 A1
(43) Pub. Date: Sep. 23, 2010

(54) Method for attachment of silicon-containing compounds to a surface and for synthesis of hypervalent silicon-compounds

(76) Inventor: Jeffery R. Owens, Fredericksburg, VA (US)

Correspondence Address: DEPARTMENT OF THE AIR FORCE, AFMC LO/JAZ, BLdg 11, Room D18, WRIGHT-PATTERSON AFB, OH, 45433-7109, US

(21) Appl. No.: 11/527,662

(22) Filed: Sep. 15, 2006

Related U.S. Application Data
(60) Provisional application No. 60/722,399, filed on Sep. 15, 2005.

(30) Foreign Application Priority Data
Apr. 28, 2006 (GB) GB 0608534.4

(51) Int. Cl. C23C 14/28

(52) U.S. Cl. 427/595

(57) ABSTRACT

A method for inducing a hypervalent state within silicon-containing compounds by which they can be chemically attached to a surface or substrate and/or organized onto a surface of a substrate. The compounds when attached to or organized on the surface may have different physical and/or chemical properties compared to the starting materials.

### CROSS-REFERENCE TO RELATED APPLICATIONS

This application claims priority under 35 U.S.C. §119(e) from U.S. provisional application Ser. No. 60/772,399, filed Sep. 15, 2005 by Jeffrey R. Owens, titled Attachment of Silanol Ether, and Silanolate Functionalized Compounds to Substrates and Surfaces Using Electromagnetic Radiation, and is fully incorporated by reference into this application.

### RIGHTS OF THE GOVERNMENT

The invention described herein may be manufactured and used by or for the Government of the United States for all governmental purposes without the payment of any royalty.

### BACKGROUND

The present application relates to a method for inducing a hypervalent state within silicon-containing compounds by which they can be chemically attached to a surface or substrate and/or organized onto a surface of a substrate. The compounds when attached to or organized on the surface may have different physical and/or chemical properties compared to the starting materials.

The chemical attachment of silicon-containing compounds to surfaces is known in the prior art. Conventionally, this is achieved by contacting a suitable surface with a suitable silicon-containing compound in the presence of an activator and heating the surface. The reaction between the surface and the silicon-containing compounds is relatively slow. Such processes usually require large amounts of solvent, curing at high temperatures and disadvantageous steps. An example of the attachment of siloxanes to a polyester/cotton fabric using the application of heat is disclosed in U.S. Pat. No. 4,417,066 to Westall.

### DETAILED DESCRIPTION

A first example embodiment provides a method for chemically attaching one or more silicon-containing compounds to a substrate, the method comprising: providing one or more silicon-containing compounds selected from siloxane compounds, silanol compounds, silyl ether compounds, silanolate compounds, halosilane compounds, silatrane compounds, and silazane compounds;

contacting one or more of the silicon-containing compounds with a surface of a substrate having one or more nucleophilic sites; and

exposing the silicon-containing compounds and the surface to electromagnetic radiation having a frequency from 0.3 to 30 GHz.

A second example embodiment provides a method for creating an array of silicon-containing compounds on a surface of a substrate, the method comprising:

providing one or more silicon-containing compounds selected from siloxane compounds, silanol compounds, silyl ether compounds, silanolate compounds, halosilane compounds, silatrane compounds, and silazane compounds;

contacting one or more of these silicon-containing compounds with a surface of a substrate; and

exposing the substrate and the silicon-containing compounds to electromagnetic radiation having a frequency of from 0.3 to 30 GHz. The substrate may have one or more nucleophilic sites on its surface or one or more compounds having nucleophilic groups, such as alcohols, may be present on the surface.

In the first and second example embodiments, the surface of the substrate may be on the exterior or interior of the substrate. The substrate may, for example, be a porous polymer matrix and the silicon-containing compounds may be arranged on or attached to the interior surfaces of the pores of the matrix.

A third example embodiment provides a method for synthesizing silicon-containing hypervalent compounds, the method comprising:

providing one or more silicon-containing compounds selected from siloxane compounds, silanol compounds, silyl ether compounds, silanolate compounds, halosilane compounds, silatrane compounds, and silazane compounds;

optionally contacting the one or more silicon-containing compounds with a surface of a substrate; and

exposing the silicon-containing compounds and, if present, the substrate to electromagnetic radiation having a frequency of from 0.3 to 30 GHz. The substrate may have one or more nucleophilic sites on its surface or one or more compounds having nucleophilic groups, such as alcohols, may be present, and if a substrate is present, they may be located on the surface of the substrate.

A fourth example embodiment provides a substrate having one or more silicon-containing compounds on the surface, wherein the one or more silicon-containing compounds have been attached to the surface by the described method.

A fifth example embodiment provides a substrate having one or more silicon-containing compounds on the surface, wherein the one or more silicon-containing compounds have been organized into the array on the surface by the described method.

A sixth example embodiment provides a hypervalent silicon-containing compound formable by the described method.

In the first, second and third example embodiments, the silicon-containing compound may be a compound of the formula I

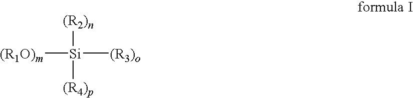

or a polymer having repeating units of formula II, which may be terminated by hydroxyl or an amine group at one or both ends of the polymer chain

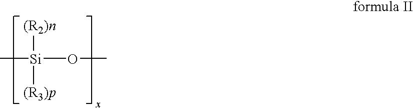

wherein R1 is hydrogen or an alkyl, preferably a C1 to C6 alkyl, more preferably, a C1 or a C2 alkyl, such as methyl or ethyl, and m is 1 to 4, preferably 3;

R2, R3 and R4 are each independently selected from alkyl, alkylglycidoxy, alkylamino, aminoalkyl, acrylate, alkylhydantoin, alkylacrylate and alkylalkene; and n, m and o are 0 to 3, providing that m+n+o+p=4.

The polymer preferably includes electron donor groups on at least some of its monomers. These electron donor groups may be substituents on R2 and/or R3 in formula II. Electron donor groups include, but are not limited to, hydroxyl, amine, sulfhydryl and carboxyl.

Alkyl is preferably a C1 to C25 alkyl, and may be C3 to C18 alkyl. Alkyl may be a substituted or non-substituted alkyl. Alkyl may be a halo-alkyl, preferably a haloalkyl in which a halo group is located at the distal end of the alkyl chain from the silicon. The haloalkyl is preferably a chloroalkyl.

Preferably, the silicon-containing compound is a compound of formula I, wherein m is 3, n is 1 and o and p are both 0, R1 is hydrogen, methyl or ethyl.

Preferably at R2, R3 and/or R4 is of the formula III

—(CH₂)_{y}—R₅ formula III

wherein Y is 1 to 5, preferably 3, R5 is selected from hydrogen, halogen, NH2, C1 to C18 alkyl, C1 to C18 alkyldimethylammonium, alkylmethacryate, preferably ethyl or propylmethacrylate, 5,5-dialkylhydantoin, preferably 5,5-dimethylhydantoin, alkylenediamine, preferably ethylenediamine, perfluoroalkyl, preferably perfluorooctyl and 3-glycidoxy.

The silicon-containing compound may comprise one or more of [3-(trimethoxysilyl)propyl]-octadecyldimethylammonium chloride, 3(3-triethoxysilylpropyl)-5,5-dimethylhydantoin, potassium trimethylsilanolate, triisopropylsilanol, methoxydimethyloctylsilane, hydroxy terminated poly(dimethylsiloxane), (3-chloropropyl)triethoxysilane, (3-chloropropyl)dimethoxymethylsilane, octadecyltrimethoxysilane, 3-aminopropyltriethoxysilane, 3-(trimethoxysilyl)propylmethacrylate, N-[3-(trimethoxysilyl)propyl]-ethylenediamine, and 3-glycidoxypropyltrimethoxysilane, 1H,1H,2H,2H-perfluorodecyltrimethoxysilane.

Preferably, the silicon-containing compound is [3-(trimethoxysilyl)propyl]-octadecyldimethylammonium chloride or 3(3-triethoxysilylpropyl)-5,5-dimethylhydantoin, 1H,1H,2H,2H-perfluorodecyltrimethoxysilane, or a mixture of them.

In the first to third example embodiments, a solution or a suspension of the silicon-containing compounds may be contacted with the substrate. The solution and/or suspension preferably comprises a polar solvent, preferably acetone and/or an alcohol, and preferably both. The alcohol preferably comprises methanol and/or ethanol. Alternatively, the silicon-containing compound may be solvent-free, that is, not in the form of a solution or suspension.

Acetone is nearly microwave transparent and has a low boiling point, so that it acts to dissipate heat via evaporation, contributing to inducing a hypervalent state within the silicon-containing compounds by exposure to electromagnetic radiation and not merely by thermal effects as in the prior art. The prior art involves thermal heating via dielectric conduction.

The substrate is preferably a material having nucleophilic sites on its surface. The nucleophilic sites may comprise one or more nucleophilic groups containing one or more of O, S and N. For example, the nucleophilic groups may be selected from OH, SH and NH2. The substrate may comprise a fabric material. It has been found that the nucleophilic groups bind to the silicon atoms of the silicon-containing compounds on contact and with exposure to electromagnetic radiation having a frequency of from 0.3 to 30 GHz. This reaction normally occurs within seconds, as opposed to hours for conventional methods, such as merely heating.

The applicant has found that the described example embodiments can produce organized alignment (that is, an array) of silicon-containing compounds on the surface of a substrate. The properties of the silicon-containing compounds often differ from those of the prior art, for example, silicon compounds attached through the use of heat. For example, the silicon-containing compounds on the substrate may have different physical and chemical properties such as increased hydrophobicity or hydrophilicity and/or increased biocidal efficacy. Without being bound by theory, it is believed that the use of microwave radiation induces a hypervalency around the silicon atom, that is, it coordinates to more than 4, possibly to 5 or 6 available ligands. When the microwave treatment is stopped, the silicon will often relax back to a tetra-coordinate state. The hypervalent state is believed to lead to a more organized arrangement of silicon-containing compounds on the surface of a substrate. Evidence that the described method induces a hypervalent state is demonstrated in the ability of the method to produce stable and known hypervalent compounds in higher yield, less time, and in higher purity than conventional chemical methods. The following reactions are provided as known conventional pathways to hypervalent compounds that were also demonstrated by the described method. Hypervalency in silicon has been shown to occur in the following known reaction between tetramethoxy silane and catechol:

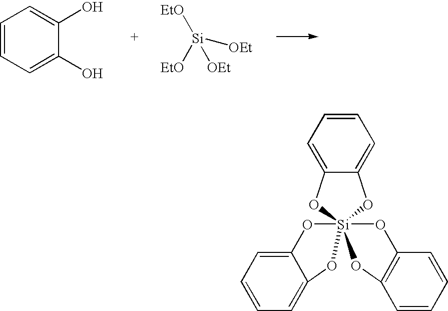

Other reactions known to result in hypervalent-silicon compounds that were also demonstrated by the present method include:

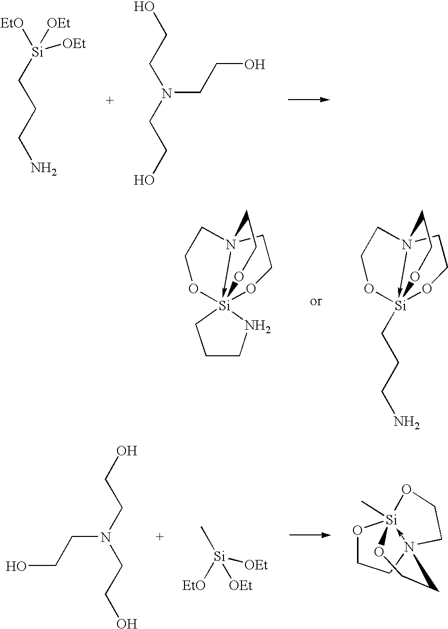

The above reactions and others that result in hypervalent silicon, and the conventional chemical methods employed for their synthesis, can be found in the following prior art documents: Chem. Rev. 1993, 93, 1371-1448, Chult et al; Chem. Rev. 1996, 96, 927-950, Holmes; and Journal of Organometallic Chemistry, 1990, 389, 159-168, Cerveau et al.

The hypervalent-silicon products produced in the above reactions are sufficiently stable to be characterized. It has been demonstrated that a similar hypervalency occurs in the process of these embodiments, although the hypervalent silicon may revert to a tetravalent silicon following microwave treatment if the hypervalent intermediate is not stable. It is surprising that, regardless of whether or not the silicon remains in a hypervalent state following the microwave treatment, a more organized arrangement of silicon-containing compounds on the surface of the substrate is observed.

Si—OR excitation via electromagnetic radiation in the presence of an appropriate electron donor facilitates the cleavage of the Si—OR bond and is believed to induce the formation of hypervalent siloxane species with available electron donors. The electron donor for this exchange can take the form of virtually any nucleophile, induced nucleophile, nucleophilic region, or Lewis base. The resulting hypervalent species is then thought to either relax into their ground state, at which time the silane species is tetracoordinate, or, if the hypercoordinated product is stable, the silane product can remain in the hypervalent state as either a pentacoordinate or hexacoordinate system. The electromagnetic excitation within the siloxane induces specific conformations within the new species, which leads to increased and specific organization in the resting state of the newly formed species. If the substrate is a polymer, the specific organization of the silicon-containing on the surface or in the matrix of a polymer can change the chemical and physical properties of the polymer as a whole. This phenomenon is not temperature dependent.

The method of these example embodiments avoids a need to use activators, catalysts and conventional curing processes. This therefore permits attaching ‘delicate’ functionalities. For example, glycidoxy containing siloxane and acrylate containing siloxanes are examples of delicate silicon containing compounds, and proteins/enzymes are examples of delicate substrates, to which one may wish to attach a silicon-containing substrate.

Preferably, the microwaves are produced using a power rating of 650 Watts or less, more preferably of from 65 to 650 Watts. The microwaves may be produced using a power rating of from 135 to 400 Watts.

Preferably, the microwaves have a frequency of from 0.3 to 10 GHz, more preferably of from 1 to 3 GHz.

To reduce the possible degradation of delicate silicon-containing compounds and/or delicate substrates, one or more of the following may be used: irradiation at a reduced power level, for example, microwaves produced using a power rating of 400 Watts or less, preferably 135 Watts or less, or subjecting the substrate and silicon-containing compounds to microwave irradiation and relaxation (no microwave irradiation) in alternating intervals: for example, a period of irradiation of preferably 5 to 30 seconds, more preferably 10 to 20 seconds, most preferably 15 seconds, followed by a period of relaxation of preferably 2 to 30 seconds, more preferably 5 to 15 seconds, most preferably 10 seconds, and optionally repeating this process as often as required. It has been found that, for many compounds containing an Si—O moiety, this is more sensitive to microwave radiation than other ‘delicate’ functionalities and therefore cleavage of the Si—O bond may be achieved without degradation of the other functionalities. This is an improvement over the prior art in which heating of silicon-containing compounds for periods to attach them to a substrate can lead to degradation of the delicate functionalities in the silicon-containing molecules, since the heat required to cleave the Si—O bond is sufficient to degrade the delicate functionalities.

The microwaves can be directed at particular portions of the substrate and therefore allows for regioselective attachment and/or arrangement of the silicon-substituted compounds and for reactions that can be initiated that would not be possible using traditional methods.

The example embodiments have been found to be far more effective in attaching silicon-containing compounds to a substrate surface compared to traditional methods such as heating and using activators—more than 80% of the silicon-containing compounds can be attached under certain conditions to the surface using the described example embodiments.

The substrate may comprise a natural material. The material may be a cloth material. The material may comprise one or more materials selected from cotton, wool and leather. The material may be woven or non-woven. The material may comprises fibers of natural and/or synthetic material. The synthetic material may comprise a woven or nonwoven fabric material to include, but not limited to, fabrics wherein the material comprises one or more of the following; cotton, polyester, nylon, wool, leather, rayon, polyethylene, polyvinylchloride, polyvinylalcohol, polyvinylamine and polyurea.

The substrate may be in the form of particles. The particles may have a diameter of from 10 nm to 1 mm, preferably 100 to 1000 nm.

The substrate may comprise a metal oxide. The metal oxide may be selected from one or more of aluminium oxide, titanium dioxide, magnesium oxide, calcium oxide, silicon dioxide and zinc oxide.

The substrate may comprise a natural mineral. The substrate may comprise one or more materials selected from kaolinite, barasym, silica, montmorillonite, vermiculite, bohemite and quartz.

The substrate may be porous. The substrate may comprise a molecular sieve. The substrate may comprise a zeolite.

The substrate may comprise a polymer. The polymer may be in the form of a porous matrix. The substrate may comprise a plastic material. The substrate may comprise polyurethane and/or nylon, polyester, nylon, rayon, polyethylene, polyvinylchloride, polyvinylalcohol, polyvinylamine and polyurea.

The substrate may comprise a carbohydrate.

In the first to third example embodiments, an alcohol may be present. The substrate may comprise an alcohol. The substrate may have an alcohol on its surface. The alcohol may comprise a diol, which may be a vicinal diol, or a triol. The alcohol may be selected from one or more of an alkyl diol, preferably a C₂ to C₂₅ alkyl diol, an alkyl triol, preferably a C3 to C25 alkyl triol and a phenyl diol, preferably a vicinal phenyl diol. Each hydroxyl group in the triol is preferably vicinal to one of the other hydroxyl groups. The alcohol may be selected from catechol, ethylene glycol or glycerol.

The substrate may comprise a silicon-dioxide based material, such as glass, silicon dioxide, sand, and silica.

The method of the described example embodiments may involve:

contacting the substrate with a silicon-containing compound as defined in this description and exposing the compounds to electromagnetic radiation having a frequency of from 0.3 to 30 GHz, and subsequently treating the substrate with a halogenating substance. The silicon-containing compound preferably comprises 3(3-triethoxysilylpropyl)-5,5-dimethylhydantoin. The halogenating substance may comprise a chlorinating substance, including, but not limited to a bleaching agent, for example a hypochlorite such as sodium hypochlorite.

Following treating the substrate with the halogenating agent, the substrate may be dried. The substrate may be dried by exposing the substrate to a temperature of 20° C. or more, preferably 30° C. or more, more preferably 35° C. for a period including, but not limited to, 1 hour or more, preferably 4 hours or more.

Consider now the following example embodiments.

### Example Embodiments

### Example 1

Separate swatches of cotton were each treated with a solution containing one of:

1. [3-(trimethoxysilyl)propyl]-octadecyldimethylammonium chloride,
2. 3(3-triethoxysilylpropyl)-5,5-dimethylhydantoin,
3. potassium trimethylsilanolate,
4. triisopropylsilanol,
5. methoxydimethyloctylsilane,
6. hydroxy terminated poly(dimethylsiloxane),
7. (3-chloropropyl)triethoxysilane,
8. (3-chloropropyl)dimethoxymethylsilane,
9. octadecyltrimethoxysilane,
10. 3-aminopropyltriethoxysilane,
11. 3-(trimethoxysilyl)propylmethacrylate,
12. N-[3-(trimethoxysilyl)propyl]-ethylenediamine, and
13. 3-glycidoxypropyltrimethoxysilane.

Each solution contained acetone, ethanol and methanol.

Each swatch of cotton was then irradiated at a frequency between 0.30-30 GHz for a period of time dependent on the properties of the silicon containing compound that was attached. All experiments were performed initially at 2.45 Ghz, with power level being varied depending on the nature of the attached functional group. In general, the procedure was first attempted at full power for two full cycles of the following program: 30 s 50% power (325 Watts), 30 s relaxation (magnetron disengaged), 30 s 50% power, 30 s relaxation, 30 s 100% power, allow to cool to room temperature, then repeat cycle. If the procedure “cracked” the reactants, then the irradiation time and power level were reduced accordingly until the procedure yielded the desired result. The samples were then washed, rinsed thoroughly and dried overnight at 35° C.

The attachment of the silicon-containing compounds was confirmed by: 1. an overall increase in weight of the cloth (all samples), 2. a change in the physical characteristics of the cloth (all), 3. biocidal efficacy of the treated fabric (2 samples, see below), 4. FTIR spectroscopy (all), 5. elemental analysis (all), and 6. ionic strength of the product in distilled, deionized water (all).

Conclusions from Example 1: 1. the method is nonspecific with respect to the type of functionality that can be attached, and the compound may comprise a silyl ether, silanol or silanolate; 2. The process works for silyl ethers, silanols and silanolates; 3. by tuning the frequency and power level, the method can be tailored to avoid degradation of with other functionalities within the system; and 4. the process works on cotton.

### Example 2

100 mg samples of nanoscale bohemite (300 nm from Sasol) were treated with one of the following solutions of:
1. [3-(trimethoxysilyl)propyl]-octadecyldimethylammonium chloride
2. 3(3-triethoxysilylpropyl)-5,5-dimethylhydantoin,
3. potassium trimethylsilanolate,
4. triisopropylsilanol,
5. methoxydimethyloctylsilane,
6. hydroxy terminated poly(dimethylsiloxane),
7. (3-chloropropyl)triethoxysilane,
8. (3-chloropropyl)dimethoxymethylsilane,
9. octadecyltrimethoxysilane,
10. 3-aminopropyltriethoxysilane,
11. 3-(trimethoxysilyl)propylmethacrylate,
12. N-[3-(trimethoxysilyl)propyl]-ethylenediamine, and
13. 3-glycidoxypropyltrimethoxysilane.

Each solution contained one or more of acetone, ethanol and methanol.

100 mg of bohemite is approximately 1 mmol. To this 1 mmol of bohemite approximately 0.1 mmol of silane dissolved in approximately 0.5-1.0 mL of acetone was added. For example, the MW of 3(3-triethoxysilylpropyl)-5,5-dimethylhydantoin is 332, so 33.2 mg of silane was dissolved in 1 mL. For these reactions, the procedure was scaled up to full molar scale. Surprisingly, the “batch” scale actually worked much better than this small scale experiment, that is, a higher and better degree of attachment of the silicon on the bohemite was observed.

The samples were then irradiated at a frequency between 0.30-30 GHz for a period of time depending on the properties of the silyl ether, silanolate or silanol that was attached. The irradiation procedure described in Example 1 was used. The samples were then washed with a minimal amount of ice cold ethanol and then twice with surfactant-containing water; the samples were then rinsed with water thoroughly and dried overnight at 35° C.

The attachment of the silicon-containing compounds was confirmed by: 1. a change in the physical characteristics of the treated nanoparticles, 2. biocidal efficacy of the treated nanoparticles (2 samples, in particular: solutions 1 and 2), 4. FTIR spectroscopy (all), 5. elemental analysis (all), and 6. ionic strength of the product in distilled, deionized water (all).

Conclusions from Example 2: 1. the process is nonspecific with respect to the type of functionality that can be attached, and the silicon-containing compounds can include a silyl ether, silanol, or silanolate; 2. by tuning the frequency and power level, the process can be tailored not to interfere with other functionalities within the system; and 3. The process works well on bohemite.

### Example 3

Two samples of each of the substrates listed below were treated with either a solution of [3-(trimethoxysilyl)propyl]-octadecyldimethylammonium chloride or a solution of 3(3-triethoxysilylpropyl)-5,5-dimethylhydantoin.

The substrate samples were: 1. cotton, 2. aluminum oxide, 3. titanium dioxide, 4. glass, 5. nylon, 6. kaolinite, 7. barasym, 8. silicon dioxide, 9. wool, 10. leather, 11. silica, 12. molecular sieves, 13. montmorillonite, 14. polyurethane, 15. ethylene glycol, 16. glycerol, 17. catechol, 18. zeolite, 19. vermiculite, 20. bohemite, 21. polyester and 22. triethanolamine.

The samples were irradiated at a frequency between 0.30-30 GHz for a period of time, all dependent on the microwave absorbing properties of the substrate. The irradiation procedure described in Example 1 above was used. The samples were then washed, rinsed thoroughly and dried overnight at 35° C. The samples treated with 3(3-triethoxysilylpropyl)-5,5-dimethylhydantoin) were also charged with dilute hypochlorite (to generate the chloramine) and again washed, rinsed and dried.

The attachment of the silicon-containing compounds to each substrate was confirmed by:

a change in the physical characteristics of the treated samples (all), 2. biocidal efficacy of the treated samples (all solid samples), 3. oxidation of iodide to elemental iodine (samples treated with 3(3-triethoxysilylpropyl)-5,5-dimethylhydantoin), 4. FTIR spectroscopy (all), 5. ionic strength of the product in distilled, deionized water (all), 6. HNMR (2 samples: those treated with triethanolamine-hydantoin silane and catechol-hydantoin silane]), and 7. GCMS (3 samples: those treated with catechol hydantoin silane, triethanolamine hydantoin silane and glycerol hydantoin silane).

Conclusions from Example 3: 1. the process will work for any substrate that contains an appropriate S, and/or O, and/or N, and/or Nu; 2. by tuning the frequency and power level, the process can be tailored not to interfere with other functionalities within the system; and 3. the irradiated materials are distinctly different from the equivalent heat treated version (from HNMR and GCMS).

### Example 4

Six swatches of 50:50 nylon:cotton cloth were each dipped one time in a known solution of 3(3-triethoxysilylpropyl)-5,5-dimethylhydantoin. The first set of three swatch samples were irradiated at a frequency between 0.30-300 GHz for a period of time as described above in Example 1. This first set of samples was then chlorinated with dilute bleach, washed, rinsed thoroughly, and dried overnight at 35° C. As a comparative Example, the second set of three swatch samples was heat cured overnight at 80° C. The second set of samples was then chlorinated with dilute bleach, washed, rinsed thoroughly, and dried overnight at 35° C. The attachment of the hydantoin functionality of both sets of samples was confirmed by FTIR, and by iodometric titration. Results demonstrated that the irradiated samples retained 80% higher chlorine content over the heat treated samples. Additionally, the irradiated samples demonstrated hypervalent character by differences in ionic strength.

Conclusion from Example 4: the irradiation process is more effective and efficient than heat treatment at attaching silyl ethers, silanols and silanolates to substrates.

### Example 5

The biocidal character of heat treated samples of 50:50 cotton:nylon were compared with irradiated samples from Example 4. Both sets of samples possessed the same active chlorine content as determined by iodometric titration. Results showed high excellent efficacy of irradiated samples to Bacillus anthracis spores, while heat treated samples demonstrated minimal activity against Bacillus anthracis spores.

Conclusions from Example 5: The irradiated materials are distinctly different from the equivalent heat treated version. The irradiation process produces a product that is a more efficient sporicide than the heat curing process.

While specific embodiments have been described in detail in this detailed description, those having ordinary skill in the art will appreciate that various modifications and alternatives to those details could be developed in light of the overall teachings of this disclosure. Accordingly, the particular arrangements and steps disclosed are illustrative only and not limiting as to the scope of the invention, which is to be given the full breadth of the claims and any and all equivalents.

1-22. (canceled)

23. A method for the chemical attachment of one or more silicon-containing compounds to a substrate, the method comprising:
providing one or more silicon-containing compounds selected from siloxane compounds, silanol compounds, silyl ether compounds, silanolate compounds, halosilane compounds, silatrane compounds, and silazane compounds;
contacting one or more of the silicon-containing compounds with a surface of a substrate having one or more nucleophilic sites thereon;
and exposing the one or more silicon-containing compounds and the surface to electromagnetic radiation having a frequency from 0.3 to 30 GHz,
whereby the one or more silicon-containing compounds become chemically attached to the surface of the substrate at the one or more nucleophilic sites.

24. A method as claimed in claim 23, wherein the one or more silicon-containing compounds attached to the substrate create an array on the surface of the substrate.

25. A method as claimed in claim 23, wherein the one or more silicon-containing compounds comprise a compound of a formula I 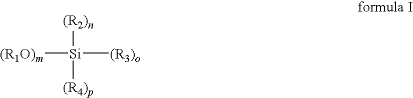
or a polymer having repeating units of formula II, which may be terminated by hydrogen or an alkyl group at one or both ends of the polymer chain, 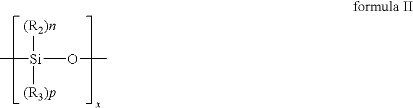
wherein R₁ is hydrogen or an alkyl and m is 1 to 3;
R₂, R₃ and R₄ are each independently selected from alkyl, alkylglycidoxy, alkylamino, aminoalkyl, acrylate, alkylhydantoin, alkylacrylate and alkylalkene;
and n, m, o and p, are 0 to 3, provided that m+n+o+p=4.

26. A method as claimed in claim 25, wherein the one or more silicon-containing compounds comprise the compound of formula I and wherein R₁ is a C₁ to C₆ alkyl.

27. A method as claimed in claim 26, wherein R₁ is a C₁ or a C₂ alkyl.

28. A method as claimed in claim 25, wherein the one or more silicon-containing compounds comprise the compound of formula I and wherein m is 3.

29. A method as claimed in claim 25, wherein the one or more silicon-containing compounds are the compound of formula I, wherein m is 3, n is 1 and o and p are both 0, R₁ is hydrogen, methyl or ethyl.

30. A method as claimed in claim 25, wherein the one or more silicon-containing compounds comprise the compound of formula I and wherein R₂, R₃ and/or R₄ is of a formula III
—(CH₂)_{y}—R₅ formula III
wherein Y is 1 to 5,
R5 is selected from hydrogen, halogen, NH₂, C₁ to C₁₈ alkyl, C₁ to C₁₈ alkyldimethylammonium, alkylmethacrylate, 5,5-dialkylhydantoin, alkylenediamine, perfluoroalkyl, and 3-glycidoxy.

31. A method as claimed in claim 25, wherein the one or more silicon-containing compounds comprise the compound of formula II, and wherein R₂ and/or R₃ is of a formula III
—(CH₂)_{y}—R₅ formula III
wherein Y is 1 to 5,
R₅ is selected from hydrogen, halogen, NH₂, C₁ to C₁₈ alkyl, C₁ to C₁₈ alkyldimethylammonium, alkylmethacrylate, 5,5-dialkylhydantoin, alkylenediamine, perfluoroalkyl, and 3-glycidoxy.

32. A method as claimed in claim 30, wherein Y is 3.

33. A method as claimed in claim 30, wherein R₅ is selected from ethyl or propylmethacrylate, 5,5-dimethylhydantoin, ethylenediamine or perfluorooctyl.

34. A method as claimed in claim 31, wherein Y is 3.

35. A method as claimed in claim 31, wherein R₅ is selected from ethyl or propylmethacrylate, 5,5-dimethylhydantoin, ethylenediamine or perfluorooctyl.

36. A method as claimed in claim 23, wherein the one or more silicon-containing compounds are selected from [3-(trimethoxysilyl)propyl]octadecyldimethylammonium chloride, 3(3-triethoxysilylpropyl)-5,5-dimethylhydantoin, potassium trimethylsilanolate, triisopropylsilanol, methoxydimethyloctylsilane, hydroxy terminated poly(dimethylsiloxane), (3-chloropropyl) triethoxysilane, (3-chloropropyl) dimethoxymethylsilane, octadecyltrimethoxysilane, 3-aminopropyltriethoxysilane, 3-(trimethoxysilyl)propylmethacrylate, N-[3-(trimethoxysilyl)propyl]-ethylenediamine, and 3-glycidoxypropyltrimethoxysilane, 1H,1H,2H,2H-perfluorodecyltrimethoxysilane.

37. A method as claimed in claim 36, wherein the one or more silicon-containing compound are selected from [3-(trimethoxysilyl)propyl]-octadecyldimethylammonium chloride and 3(3-triethoxysilylpropyl)-5,5-dimethylhydantoin.

38. A method as claimed in claim 23, wherein the nucleophilic sites comprise one or more nucleophilic groups containing one or more of 0, S and N.

39. A method as claimed in claim 23, wherein the substrate comprises a woven or nonwoven fabric material.

40. A method as claimed in claim 39, wherein the fabric material is selected from one or more of cotton, polyester, nylon, wool, leather, rayon, polyethylene, polyvinylchloride, polyvinylalcohol, polyvinylamine and polyurea.

41. A method as claimed in claim 23, wherein the substrate comprises one or more materials selected from aluminum oxide, titanium dioxide, glass, nylon, kaolinite, barasym, silicon dioxide, silica, molecular sieves, montmorillonite, polyurethane, ethylene glycol, glycerol, catechol, zeolite, vermiculite, and bohemite.

42. A method as claimed in claim 23, the method comprising contacting the substrate with 3(3-triethoxysilylpropyl)-5,5-dimethylhydantoin, exposing the compounds to electromagnetic radiation having a frequency of from 0.3 to 30 GHz, and subsequently treating the substrate with a halogenating substance.
